(19) United States
(12) Patent Application Publication
(10) Pub. No.: US 2023/0052439 A1
(43) Pub. Date: Feb. 16, 2023

(54) DETECTING AND RESPONDING TO LIGHT SOURCE FAILURE

(71) Applicant: HEWLETT-PACKARD DEVELOPMENT COMPANY, L.P., Spring, TX (US)

(72) Inventors: Joseph Nouri, 3390 E. Harmony Rd., CO (US); Mark Lessman, Fort Collins, CO (US)

(73) Assignee: HEWLETT-PACKARD DEVELOPMENT COMPANY, L.P., Spring, TX (US)

(21) Appl. No.: 17/777,689

(22) PCT Filed: Nov. 18, 2019
(86) PCT No.: PCT/US2019/061978

§ 371 Date: May 18, 2022

(51) Int. Cl. G02B 27/01; B81B 7/02; G06F 3/01

(52) U.S. Cl. CPC G02B 27/0176; G02B 27/0172; B81B 7/02; G06F 3/013; G02B 2027/0138; H01S 5/183

(57) ABSTRACT

In various examples, a head-mountable display (“HMD”) may include a light source to emit light across a target region of a wearer, a light sensor, and a circuitry operably coupled with the light source and the light sensor. The circuitry may operate the light source to periodically emit light across the light sensor. Based on a determination that a time interval since the circuitry last received a signal from the light sensor satisfies a threshold, the circuitry may trigger a remedial action to cause the light source to cease emission of light across the target region of the wearer.

### BACKGROUND

With some types of immersive computing, an individual wears a head-mountable display (“HMD”) in order to have an eXtended Reality (“XR”) experience, which may include augmented reality (“AR”), mixed reality (“MR”), and virtual reality (“VR”) experience. Eye tracking is an element of immersive computing that enables features such as user selection of virtual objects rendered in a XR landscape. In some immersive computing systems such as XR HMDs, microelectromechanical system (“MEMS”) emitters may be employed to detect various features of a wearer's eye, e.g., for eye tracking purposes. For example, a MEMS emitter may be operated to irradiate (e.g., scan, sweep) the wearer's eye with coherent and/or collimated electromagnetic radiation, e.g., in the infrared (“IR”) range. The amount of electromagnetic radiation (also referred to herein simply as “light”) to which the wearer's eye is exposed is generally considered safe, even for prolonged time intervals, such as if the MEMS emitter becomes stuck.

### BRIEF DESCRIPTION OF THE DRAWINGS

Features of the present disclosure are illustrated by way of example and not limited in the following figure(s), in which like numerals indicate like elements.

FIG. 1 depicts an example environment in which selected aspects of the present disclosure may be implemented.

FIGS. 2A, 2B, and 2C depict various examples of how selected aspects of the present disclosure may be implemented.

FIG. 3 is a perspective view depicting an example HMD configured with selected aspects of the present disclosure.

FIG. 4 is a (flow) diagram that demonstrates how a MEMS emitter may be disabled according to an example.

FIG. 5 is a flow diagram that depicts an example method for practicing selected aspects of the present disclosure.

### DETAILED DESCRIPTION

For simplicity and illustrative purposes, the present disclosure is described by referring mainly to an example thereof. In the following description, numerous specific details are set forth in order to provide a thorough understanding of the present disclosure. However, the present disclosure may be practiced without limitation to these specific details. In other instances, some methods and structures have not been described in detail so as not to unnecessarily obscure the present disclosure.

The elements depicted in the accompanying figures may include additional components and that some of the components described in those figures may be removed and/or modified without departing from scopes of the elements disclosed herein. The elements depicted in the figures may not be drawn to scale and thus, the elements may have different sizes and/or configurations other than as shown in the figures.

As noted previously, the amount of electromagnetic radiation to which an individual's eye is exposed by a MEMS emitter installed in an HMD is in many cases considered safe, even for prolonged time intervals, such as when the MEMS emitter is stuck. However, there may be applications and/or situations in which a MEMS emitter emits an amount of electromagnetic that is not considered safe. In any case, the safest option would be to cease exposing the wearer's eye to the IR light altogether.

While it is possible to control a MEMS emitter with machine-executable instructions, these instructions may be released and/or controlled by a different entity than that which manufactures and/or distributes a device in which the MEMS emitter is installed. Consequently, the manufacturer/distributor may lack the ability to implement MEMS emitter safety features using machine-executable instructions. Additionally, machine-executable instructions and the memory in which they are stored are not immune to failure. Memory in which these instructions are stored can become corrupted, e.g., as a result of errors that originate in hardware and/or in machine-executable instructions (e.g., memory overruns).

Accordingly, examples are described herein for detecting when a MEMS emitter becomes stuck or stalled in a configuration, and for taking remedial actions in response. In various examples, a MEMS emitter may be operated, periodically and/or on demand, to scan a target feature, such as an eye of a wearer of an HMD. In some such examples, light reflected from the wearer's eye may be detected by a light sensor, such as a photodiode, which may generate a signal indicative of the reflective light. That signal may be analyzed to, for instance, perform eye tracking.

Meanwhile, in some examples, the MEMS emitter may also be operated to periodically emit light across another “safety” light sensor/collector, such as a distinct photodiode. In the event the MEMS emitter fails to irradiate the safety light sensor with light for some period of time, e.g., over a predetermined time interval and/or after a counter is incremented past some threshold, various remedial actions may be taken. The various remedial actions may include, but are not limited to, turning off the MEMS emitter, raising an audible or visual alarm, e.g., on a display of a HMD, attempting to recalibrate or reset the MEMS emitter, and so forth.

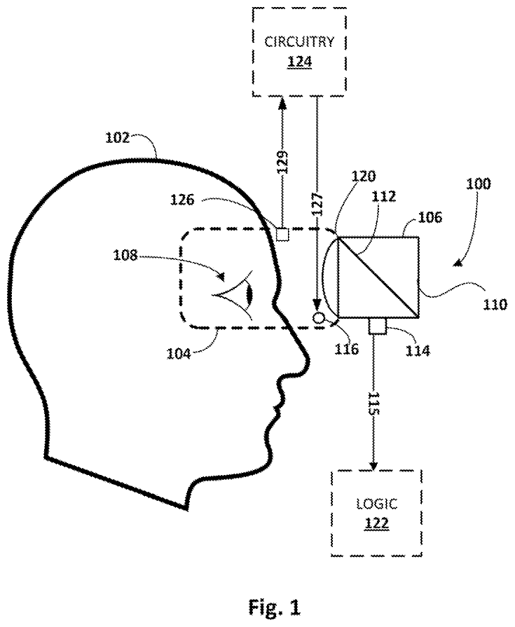

Referring now to FIG. 1, an example head-mountable display (“HMD”) 100 configured with selected aspects of the present disclosure is depicted schematically as HMD 100 might be worn by an individual 102, which in the present context may also be referred to as a “user” or “wearer.” In FIG. 1, HMD 100 includes a first housing 104 and a second housing 106. However, in other examples, other housing configurations may be provided. First housing 104 encloses, among other things, an eye 108 of individual 102, which in this case is the individual's right eye. Although not visible in FIG. 1 due to the viewing angle, in many examples, first housing 104 may also enclose another eye of individual 102, which in this case would be the individual's left eye.

Second housing 106 may include some or all of the circuitry of HMD 100 that are operated to provide individual 102 with an immersive computing experience. For example, in FIG. 1, second housing 106 includes a display 110, which in many cases may include two displays, one for each eye 108 of individual 102, that collectively render content in stereo. By rendering virtual content on display 110, HMD 100 provides individual 102 with a XR-based immersive computing experience in which individual 102 may interact with virtual objects, e.g., using his or her gaze. In some such examples, first housing 104 may completely enclose the eyes of individual 102, e.g., using a “skirt” or “face gasket” of rubber, synthetic rubber, silicone, or other similar materials, in order to prevent outside light from interfering with the individual's XR experience. In some such examples, various components of FIG. 1 may be omitted, sized differently, and/or arranged differently to accommodate different needs.

HMD 100 includes a light source 116, a light sensor 114, and logic 122 as shown in FIG. 1. Light source 116 may take various forms. In some examples, light source 116 may take the form of a MEMS emitter that emits a coherent and/or collimated beam of IR light. In some such examples, the MEMS emitter may include a vertical-cavity surface-emitting laser (“VCSEL”). In some examples, Eight source 116 may take the form of IR light-emitting diodes (“LED”). Light sensor 114 also may take various forms. In some examples, light sensor 114 may be an IR camera that detects electromagnetic radiation between 400 nm to 1 mm, or, in terms of frequency, from approximately 430 THz to 300 GHz.

In some examples, including that of FIG. 1, a mirror 112 may be provided in second housing 106. Mirror 112 may be angled relative to second housing 106. Mirror 112 is tilted so that a field of view (“FOV”) of light sensor 114 is able to capture eye 108 of individual 102. Light source 116 may be located in first housing 104 and may be operated to emit light that is reflected from eye 108 to mirror 112, which redirects the light towards light sensor 114. In some examples, mirror 112 may be specially designed to allow non-IR light to pass through, such that content rendered on display 110 is visible to eye 108, while IR light is reflected towards light sensor 114. For instance, mirror 112 may take the form of a dielectric mirror, e.g., Bragg mirror. In some examples, mirror 112 may be coated with various materials to facilitate IR reflection, such as silver or gold. In other examples, light sensor 114 (and light source 116) may operate in other spectrums, such as the visible spectrum, in which case light sensor 114 could be an RGB camera.

The example of FIG. 1 is not meant to be limiting, and light source 116, light sensor 114, or multiple light sources or sensors, may be deployed elsewhere on or within HMD 100, In some examples, increasing the number of light sources or sensors may increase the accuracy of eye tracking techniques described herein and/or the measurements they generate. In some examples, two sets of light sources and sensors may be deployed, one for each eye of individual 102.

In some examples, various optics 120 may be provided, e.g., at an interface between first housing 104 and second housing 106. Optics 120 may serve various purposes and therefore may take various forms. In some examples, display 110 may be relatively small, and optics 120 may serve to magnify display 110, e.g., as a magnifying lens. In some examples, 120 optics may take the form of a Fresnel lens, which may be lighter, more compact, and/or most cost-effective than a non-Fresnel magnifying lens. Using a Fresnel lens may enable first housing 104 and/or second housing 106 to be manufactured into a smaller form factor.

HMD 100 may facilitate eye tracking in various ways. In some examples, light source 116 may emit light into first housing 104. This emitted light may reflect from eye 108 in various directions, including towards mirror 112. As explained previously, mirror 112 may be designed to allow non-IR light to pass through, and to reflect IR light towards light sensor 114. Light sensor 114 may capture a first signal 115 that is then provided to logic 122 that is integral with, or remote from, HMD 100. First signal 115 may take the form of, for example, a sequence of images captured by light sensor 114.

Logic 122 may perform various types of image processing on these images to determine various aspects of eye 108, such as the eye's pose (or orientation), pupil dilation, pupil orientation, a measure of eye openness, etc. Logic 122 may take various forms, such as a processor that executes instructions stored in computer-readable memory (not depicted), a field-programmable gate array (“FPGA”), an application-specific integrated circuit (“ASIC”), and so forth.

To safeguard against situations in which light source 116 (e.g., MEMS emitter) becomes stuck in a position in which light source 116 continuously irradiates eye 108 or a portion thereof with IR light, HMD 100 may include a second (“safety”) light sensor 126 besides light sensor 114. Second light sensor 126 may be located in a distinct location from light sensor 114, and in some examples may be located in an area that does not interfere with a line of sign between eye 108 and mirror 112. Second light sensor 126 may take various forms. In some examples, second light sensor 126 may be a photodiode that operates as an IR light collector.

Circuitry 124 may be operably coupled with light source 116 and second light sensor 126 for detecting and responding to situations in which light source 116 becomes stuck irradiating the same area of individual 102, such as their eye 108. In some examples, second light sensor 126 may provide a signal 129 to circuitry 124. Based on characteristic(s) of signal 129 (or lack thereof), circuitry 124 may detect when second light sensor 126 does not receive IR light emitted from light source 116 for a set duration. In some examples, circuitry 124 may take a remedial action when signal 129 fails to satisfy a criterion, such as signal 129 being received by circuity 124 prior to expiration of a timer or prior to a counter being incremented to a predetermined value.

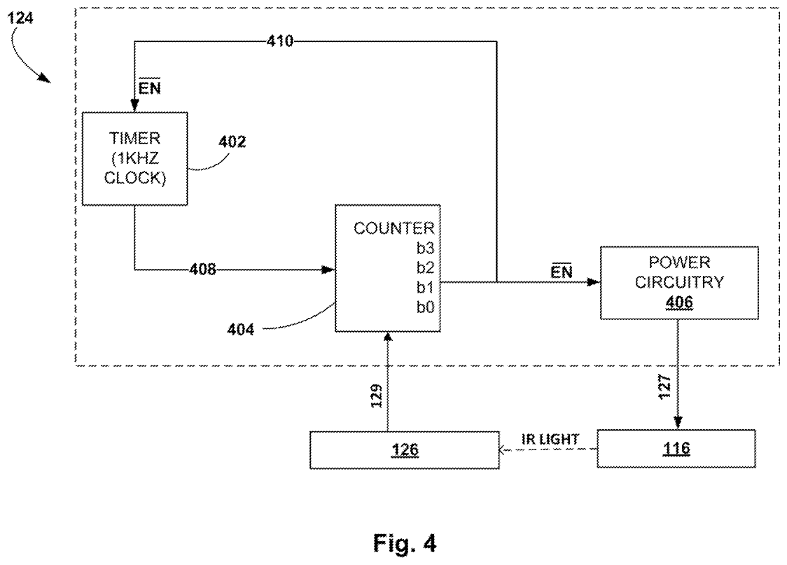

In some examples, when signal 129 fails to satisfy the criterion, circuitry 124 may generate an output 127 that triggers a remedial action, e.g., turning off light source 116 to stop emitting light across eye 108 of individual 102. The target region may be eye 108 of individual 102. The various remedial actions may also include, but are not limited to, outputting a notification to individual 102 via an output component of HMD 100, such as an audible alarm or a visual warning message on display 110 of HMD 100, or attempting to recalibrate or reset the MEMS emitter, etc. Circuitry 124 will be discussed in more detail with respect to FIG. 4.

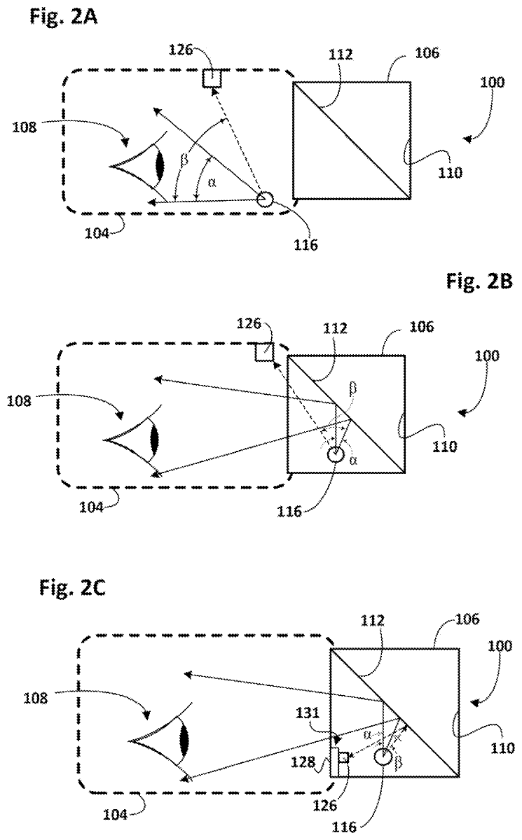

A variety of configurations for light source 116 and second light sensor 126 are available for detecting failure of light source 116, e.g., MEMS emitter failure. FIGS. 2A-C respectively depict three example configurations. In the first example as shown in FIG. 2A, light source 116 is located at a bottom portion of first housing 104, and second light sensor 126 is located at an upper portion of first housing 104, in line of sight of light source 116. Light source 116 may be operated to periodically and/or on demand to irradiate (e.g., scan, sweep) eye 108 of a HMD wearer and second light sensor 126 with the IR light. The scan range from light source 116 targeting eye 108 alone is labeled with a, while the scan range from light source 116 targeting both eye 108 and second light sensor 126 is labeled with β. As shown in FIG. 2A, the scan range β is wider than the scan range α, as second light sensor 126 is located outside of the scan range α for eye 108. In such examples, both eye 108 and second light sensor 126 may receive the IR light directly from light source 116.

In the second example as shown in FIG. 2B, light source 116 is located at a bottom portion of second housing 106, and second light sensor 126 is located at the upper portion of first housing 104 (similar as FIG. 2A). Light source 116 may be operated to emit the IR light that is reflected from mirror 112, which redirects the IR light towards eye 108. Additionally, light source 116 may scan even farther to directly irradiate second sensor 126. In other words, eye 108 receives the IR light indirectly from light source 116 as the IR light is reflected once by mirror 112. Second sensor 126 receives the IR directly in FIG. 2B, The scan range β to irradiate both eye 108 and second light sensor 126 is once again broader than the scan range a for eye 108 alone, as second light sensor 126 is located outside the scan range a for eye 108.

In the third example as shown in FIG. 2C, light source 116 is located at the bottom portion of second housing 106 similar as FIG. 2B, and second light sensor 126 is mounted on an interior surface 128 of a rim 131 that separates first housing 104 from second housing 106. In this example, both eye 108 and second light sensor 126 receive the IR light indirectly from light source 116 as the IR light is reflected by mirror 112 first. The scan range β to irradiate both eye 108 and second light sensor 126 is once again broader than the scan range α to irradiate eye 108 alone, as second light sensor 126 is located outside the scan range α for eye 108.

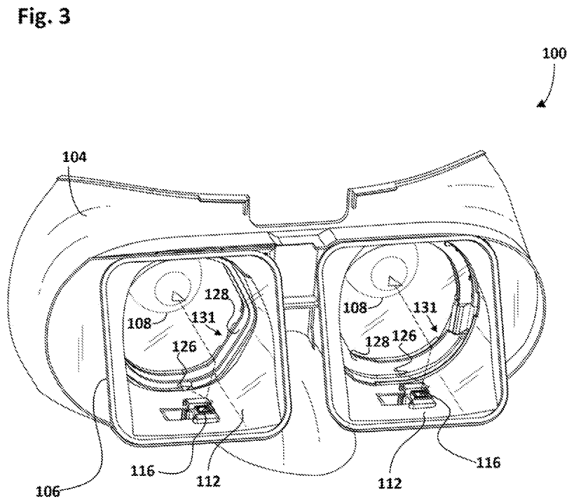

FIG. 3 is a perspective view depicting an HMD corresponding to the configuration in FIG. 2C. As shown in FIG. 3, light source 116 may be located on a bottom inner surface of a compartment attached to mirror 112 in second housing 106. Second light sensor 126 may be mounted on interior surface 128 of rim 131 of HMD 100. In such examples, mirror 112 may reflect the IR light from light source 116 towards both eye 108 and second light sensor 126.

While light source 116 and second light sensor 126 are depicted in several particular locations of HMD 100 in FIGS. 2A-C and FIG. 3, this is not meant to be limiting. Light source 116 and second light sensor 126 may be located on or with HMD 100 at any number of locations. In some examples, light source 116 and second light sensor 126 may be installed within HMD 100, e.g., during manufacturing. In other examples, light source 116 and/or second light sensor 126 may be a modular component that can be removably installed on or within HMD 100.

Referring now to FIG. 4, in some examples, circuitry 124 may include a timer 402, a counter 404, and power circuitry 406. In various examples, timer 402 may take the form of and/or be tied to cycles of a hardware-based clock, such as a 1 KHZ clock, that generates timer output 408, Counter 404 may be a binary counter such as a digital circuit counter that receives, as input, timer output 408, and generates counter output 410. In some examples, counter 404 may include sequential logic implemented with, e.g., a digital flip-flop for each binary bit, e.g., the count value of b₀ may change from zero to one with one flip-flop, and then the count value of b₁ may change from zero to one with one flip-flop, and so on.

Timer 402 may be operated to generate timer output 408, such as a clocking pulse, which is directed as input to counter 404 to increment a count. In FIG. 4, the count is implemented using four bits, b0-b3, but this is not meant to be limiting. In the example in FIG. 4, counter output 410 is tied to the count value of b3. Accordingly, when the count reaches eight (1000 in binary), b3 is equal to one. This is fed back to timer 402 as a not-enabled (E̅N̅) input. Accordingly, until the count reaches eight, b3 is equal to zero, and the E̅N̅ input of timer 402 is equal to one, and timer 402 continues to generate timer output 408. However, once b3 equals one, the input to timer is set to zero, which disables timer 402.

Additionally, counter output 410 is also tied to power circuitry 406 via another E̅N̅ input, Accordingly, and similar to timer 402, when b3 equals zero, the input to power circuitry 406 is one, and power circuitry continues to provide signal to light source 116, which continues to irradiate (periodically) second sensor 126 with IR light. However, when b3 equals one, theE̅N̅ input of power circuitry 406 goes to zero, and power circuitry 406 disables light source 116. In some examples, whenever second light sensor 126 receives IR light, second light sensor 126 sends a reset signal 129 to counter 404, which causes b0-b3 to be reset to zero.

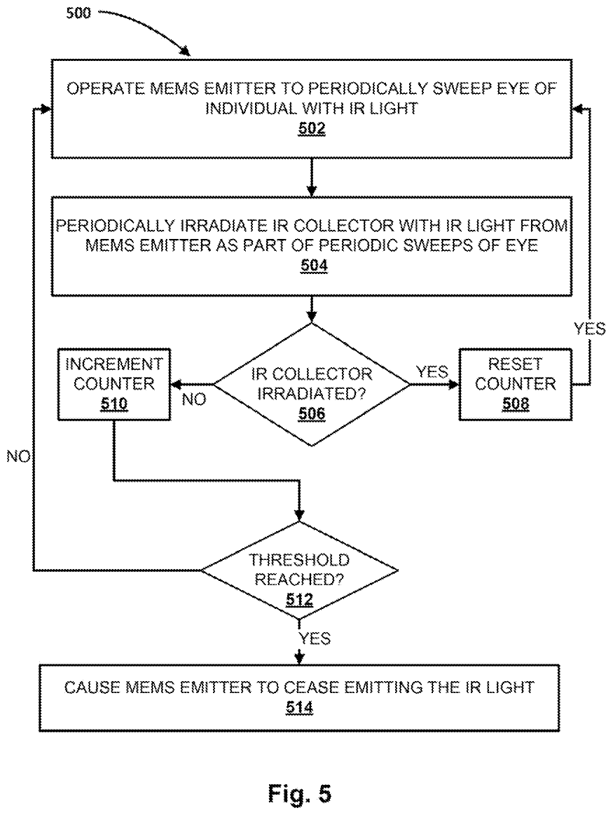

FIG. 5 illustrates a flowchart of an example method 500 for practicing selected aspects of the present disclosure. The operations of FIG. 5 may be performed by a system, such as a power circuit. For convenience, operations of method 500 will be described as being performed by a system configured with selected aspects of the present disclosure, such as a system of FIG. 1. Other implementations may include additional operations than those illustrated in FIG. 5, may perform operations (s) of FIG. 5 in a different order and/or in parallel, and/or may omit various operations of FIG. 5.

Referring to FIGS. 1 and 5, at block 502, the system may operate light source 116 associated with HMD 100 (e.g., a MEMS emitter) to periodically sweep eye 108 of individual 102 with IR light. In some examples, operating light source 116, to periodically sweep the eye of the individual may include operating the MEMS emitter to emit the IR light towards mirror 112, wherein mirror 112 reflects the IR light towards eye 108 of individual 102. In other examples, light source 116 may emit light directly towards eye 108. Although IR light is repeatedly mentioned in examples herein, this is not meant to be limiting, Other frequencies of electromagnetic radiation may be used in addition to or instead of IR radiation.

At block 504, the system may irradiate second light sensor 126 with the IR light from light source 116 periodically as part of the periodic sweeps of the eye. For example, at one extreme end of a sweep or another, light source 116 may irradiate second sensor 126, as shown in FIGS. 2A-C.

At block 506, the system, e.g., by way of circuitry 124, may determine whether second light sensor 126 was irradiated by IR light from light source 116 during one of the periodic sweeps of eye 108. If the answer is yes, then at block 508, the system, e.g., by way of circuitry 124, may reset the counter (e.g., 404) and return to block 502.

However, if the answer at block 506 is no, then at block 510, the system, e.g., by way of circuitry 124, may increment the count value of counter 404. At block 512, the system, e.g., by way of circuitry 124, may determine whether the counter has reached some predetermined threshold. In FIG. 4, the predetermined threshold was eight because b3 was tied to both timer 402 and power circuitry 406. However, this is not meant to be limiting, and any threshold may be employed. For example, if there were a b4 bit, then the threshold could be a count of sixteen.

If the answer at block 512 is no, then method 500 may proceed back to block 502. However, if the answer at block 512 is yes, then at block 514, the system may take remedial action. For example, circuitry 124 may cause light source 116 to cease emitting light, In some examples, an alarm may be raised, and output notifying the user may be provided audibly or visually.

In one aspect, an HMD may include: a light source to emit light across a target region of a wearer; a light sensor; and circuitry operably coupled with the light source and the light sensor, wherein the circuitry is to: operate the light source to periodically emit light across the light sensor; and based on a determination that a time interval since the circuitry last received a signal from the light sensor satisfies a threshold, trigger a remedial action to cause the light source to cease emitting light across the target region of the wearer.

In various examples, the target region of the wearer comprises an eye of the wearer. In various examples, the light sensor comprises a first light sensor, and the HMD comprises a distinct second light sensor to generate another signal that is used by the circuitry to track the eye of the wearer.

In various examples, the light source comprises a MEMS emitter that is to emit coherent or collimated IR light. In some examples, the MEMS emitter comprises a VCSEL. In some examples, the HMD further includes a timer, wherein the circuitry is to determine the time interval since the circuitry last received the signal from the light sensor based on another signal from the timer.

In various examples, the HMD further includes a counter, wherein the circuitry is to determine the time interval since the circuitry last received the signal from the light sensor based on the counter. In various examples, the remedial action comprises automatically turning off the light source. In various examples, the remedial action comprises outputting a notification to the wearer via an output component of the HMD. In various examples, the light sensor is mounted on an interior rim surface of the HMD.

In another aspect, a method may include: operating a MEMS emitter to periodically sweep an eye of an individual with IR light, wherein as part of the periodic sweeps of the eye, the MEMS emitter periodically irradiates an IR collector with the IR light: increment a counter in response to a determination that, during one of the periodic sweeps of the eye by the MEMS emitter, the IR collector was not irradiated by the IR light emitted by the MEMS emitter; and based on a determination that counter satisfies a threshold, causing the MEMS emitter to cease emitting the IR light.

In another related aspect, a system may include: a MEMS emitter to emit a collimated or coherent beam of light across an individual's eye; a first light sensor to generate a first signal based on light reflected from the individual's eye; a second light sensor to generate a second signal based on light emitted by the MEMS emitter directly or indirectly towards a location of the second sensor; and circuitry to perform eye tracking based on the first signal and to take a remedial action when the second signal fails to satisfy a criterion. In some examples, the criterion includes the second signal being received by the circuitry; prior to expiration of a timer; or prior to a counter being incremented to a predetermined value.

Although described specifically throughout the entirety of the instant disclosure, representative examples of the present disclosure have utility over a wide range of applications, and the above discussion is not intended and should not be construed to be limiting, but is offered as an illustrative discussion of aspects of the disclosure.

What has been described and illustrated herein is an example of the disclosure along with some of its variations. The terms, descriptions and figures used herein are set forth by way of illustration and are not meant as limitations. Many variations are possible within the scope of the disclosure, which is intended to be defined by the following claims—and their equivalents—in which all terms are meant in their broadest reasonable sense unless otherwise indicated.

What is claimed is:

1. A head-mountable display (“HMD”) comprising;
a light source to emit light across a target region of a wearer;
a light sensor: and
circuitry operably coupled with the light source and the light sensor, wherein the circuitry is to:
operate the light source to periodically emit light across the light sensor; and
based on a determination that a time interval since the circuitry last received a signal from the light sensor satisfies a threshold, trigger a remedial action to cause the light source to cease emitting fight across the target region of the wearer.

2. The HMD of claim 1, wherein the target region of the wearer comprises an eye of the wearer.

3. The HMD of claim 2, wherein the fight sensor comprises a first light sensor, and the HMD comprises a distinct second light sensor to generate another signal that is used by the circuitry to track the eye of the wearer.

4. The HMD of claim 1, wherein the fight source comprises a microelectromechanical systems (“MEMS”) emitter that is to emit coherent or collimated infrared (“IR”) light.

5. The HMD of claim 4, wherein the MEMS emitter comprises a vertical-cavity surface-emitting laser (“VCSEL”).

6. The HMD of claim 1, further comprising a timer, wherein the circuitry is to determine the time interval since the circuitry last received the signal from the light sensor based on another signal from the timer.

7. The HMD of claim 1, further comprising a counter, wherein the circuitry is to determine the time interval since the circuitry last received the signal from the fight sensor based on the counter,

8. The HMD of claim 1, wherein the remedial action comprises automatically turning off the fight source.

9. The HMD of claim 1, wherein the remedial action comprises outputting a notification to the wearer via an output component of the HMD.

10. The HMD of claim 1, wherein the light sensor is mounted on an interior rim surface of the HMD,

11. A method, comprising:
operating a microelectromechanical systems (“MEMS”) emitter to periodically sweep an eye of an individual with infrared (“IR”) light, wherein as part of the periodic sweeps of the eye, the MEMS emitter periodically irradiates an IR collector with the IR light;
increment a counter in response to a determination that, during one of the periodic sweeps of the eye by the MEMS emitter, the IR collector was not irradiated by the IR light emitted by the MEMS emitter; and
based on a determination that counter satisfies a threshold, causing the MEMS emitter to cease emitting the IR light.

12. The method of claim 11, wherein the counter is tied to cycles of a clock that is integral with a head-mountable display (“HMD”).

13. The method of claim 11, wherein operating the MEMS emitter to periodically sweep the eye of the individual comprises operating the MEMS emitter to emit the IR light towards a mirror, wherein the mirror reflects the IR light towards the eye of the individual, and wherein the IR collector is positioned in line of sight of the MEMS emitter.

14. A system comprising:
a microelectromechanical systems (“MEMS”) emitter to emit a collimated or coherent beam of light across an individual's eye;
a first light sensor to generate a first signal based on light reflected from the individual's eye;
a second light sensor to generate a second signal based on light emitted by the MEMS emitter directly or indirectly towards a location of the second sensor; and
circuitry to perform eye tracking based on the first signal and to take a remedial action when the second signal fails to satisfy a criterion.

15. The system of claim 14, wherein the criterion comprises the second signal being received by the circuitry:
prior to expiration of a timer; or
prior to a counter being incremented to a predetermined value.
